(19) United States
(12) Patent Application Publication
(10) Pub. No.: US 2026/0190810 A1
(43) Pub. Date: Jul. 2, 2026

(54) DISPLAY DEVICE

(71) Applicant: LG Display Co., Ltd., Seoul (KR)

(72) Inventors: Hyunjik BAE, Daegu (KR); Minho LEE, Daegu (KR)

(73) Assignee: LG Display Co., Ltd., Seoul (KR)

(21) Appl. No.: 19/403,679

(22) Filed: Nov. 28, 2025

(30) Foreign Application Priority Data
Dec. 31, 2024 (KR) 10-2024-0202391

(51) Int. Cl. H10K 59/80

(52) U.S. Cl. CPC H10K 59/879

(57) ABSTRACT

A display device can include a first sub pixel and a second sub pixel disposed on a substrate and configured to emit a same color of light, a first light emitting diode disposed in the first sub pixel, a second light emitting diode disposed in the second sub pixel, a first inclined insulating portion disposed on the first light emitting diode, and a second inclined insulating portion disposed on the second light emitting diode. Also, the display device can further include a first lens disposed on the first inclined insulating portion and configured to change a direction of light emitted from the first light emitting diode, and a second lens disposed on the second inclined insulating portion and configured to change a direction of light emitted from the second light emitting diode.

### CROSS-REFERENCE TO RELATED APPLICATIONS

This application claims priority to Korean Patent Application No. 10-2024-0202391 filed on Dec. 31, 2024, in the Republic of Korea, the entirety of which is incorporated herein by reference.

### BACKGROUND

### Field

The present disclosure relates to a display device, and more particularly, to a display device capable of displaying two different images on one display panel.

### Description of the Related Art

As technology advances in modern society, display devices are being widely utilized to provide information to users. A display device can be included not only in an electronic board that simply transmits visual information in a one-way manner, but also in various electronic devices that require more advanced technology to recognize a user's input and provide information in response to the recognized input.

Representative examples of display devices include a liquid crystal display device (LCD), a field emission display device (FED), an electro-wetting display device (EWD), and an organic light emitting display device (OLED).

Among these, the organic light emitting display device is a self-emissive type display device, and unlike the liquid crystal display device, it does not require a separate light source, thereby allowing lightweight and thin fabrication. In addition, the organic light emitting display device is advantageous in terms of power consumption due to low-voltage driving, and also has excellent performance in color representation, response speed, viewing angle, and contrast ratio (CR), so it is expected to be utilized in various fields.

Multi-view display technologies that can present distinct visual information to different viewers from a single screen are increasingly being sought after. However, many challenges exist such as effectively isolating the light paths for each view without incurring significant drawbacks and complexity. For example, prior approaches often result in viewing zones that have diminished brightness and crosstalk interference, a narrower viewing angle, and/or require complex and costly manufacturing processes.

Thus, there exists a need for a display configuration that can deliver high quality, independent images to multiple viewers while maintaining display brightness and simplifying production.

### SUMMARY OF THE DISCLOSURE

An object to be achieved by the present disclosure is to provide a display device with an improved function of allowing two different images to be viewed depending on a viewing angle by using one display panel.

Another object to be achieved by the present disclosure is to provide a process-optimized display device capable of forming a barrier that limits a light path without adding a separate wiring layer, thereby reducing production energy for forming the barrier.

Objects of the present disclosure are not limited to the above-mentioned objects, and other objects, which are not mentioned above, can be clearly understood by those skilled in the art from the following descriptions.

A display device according to an example embodiment of the present disclosure includes: a substrate in which a first sub pixel and a second sub pixel emitting the same color are defined; a first light emitting diode disposed on the substrate and disposed in the first sub pixel; a second light emitting diode disposed on the substrate, disposed in the second sub pixel, and emitting the same color as the first light emitting diode; an insulating layer disposed above the first light emitting diode and the second light emitting diode; a first additional insulating layer disposed on the insulating layer and including a first inclined surface overlapping the first light emitting diode; a second additional insulating layer disposed on the insulating layer, overlapping the second light emitting diode, and including a second inclined surface inclined in a direction different from the first inclined surface; a first light path changing part disposed on the first inclined surface; a second light path changing part disposed on the second inclined surface; and a barrier part disposed on the first additional insulating layer and the second additional insulating layer and covering a part of top surfaces of the first light path changing part and the second light path changing part.

A display device according to another example embodiment of the present disclosure includes; a substrate in which a first sub pixel in which light is emitted in a first direction and a second sub pixel emitting the same color as the first sub pixel and in which light is emitted in a second direction different from the first direction are defined; a first light emitting diode disposed on the substrate and disposed in the first sub pixel; a second light emitting diode disposed on the substrate, disposed in the second sub pixel, and emitting the same color as the first light emitting diode; an insulating layer disposed above the first light emitting diode and the second light emitting diode; a first additional insulating layer disposed on the insulating layer and including a first inclined surface overlapping the first light emitting diode; a second additional insulating layer disposed on the insulating layer, overlapping the second light emitting diode, and including a second inclined surface inclined in a direction different from the first inclined surface; a first light path changing part disposed on the first inclined surface and changing a light path of light emitted from the first light emitting diode to the first direction; a second light path changing part disposed on the second inclined surface and changing a light path of light emitted from the second light emitting diode to the second direction; and a barrier part disposed on the first additional insulating layer and the second additional insulating layer and covering a part of top surfaces of the first light path changing part and the second light path changing part.

Other detailed matters of the example embodiments are included in the detailed description and the drawings.

The present disclosure can enhance reliability of a function of viewing two different contents respectively on left and right sides by using one display panel.

The present disclosure can enhance reliability of a function of an optical member by disposing the optical member on a planarized insulating layer.

The present disclosure can form a barrier that limits a light path without adding separate wiring line, thereby reducing production energy for forming the barrier and optimizing a manufacturing process of the display device.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an example diagram of a display device according to an example embodiment of the present disclosure;

FIG. 2 is a functional block diagram of a display device according to an example embodiment of the present disclosure;

FIG. 3A is an enlarged plan view of one pixel of a display device according to an example embodiment of the present disclosure;

FIG. 3B is an enlarged plan view of one first sub pixel of a display device according to an example embodiment of the present disclosure;

FIG. 3C is an enlarged plan view of one second sub pixel of a display device according to an example embodiment of the present disclosure;

FIG. 4 is a cross-sectional view taken along line A-A′ of FIG. 3 according to an example embodiment of the present disclosure;

FIG. 5 is a cross-sectional view taken along line B-B′ of FIG. 3 according to an example embodiment of the present disclosure;

FIG. 6 is an enlarged plan view of one pixel of a display device according to another example embodiment of the present disclosure; and

FIG. 7 is a cross-sectional view taken along line C-C′ of FIG. 6 according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

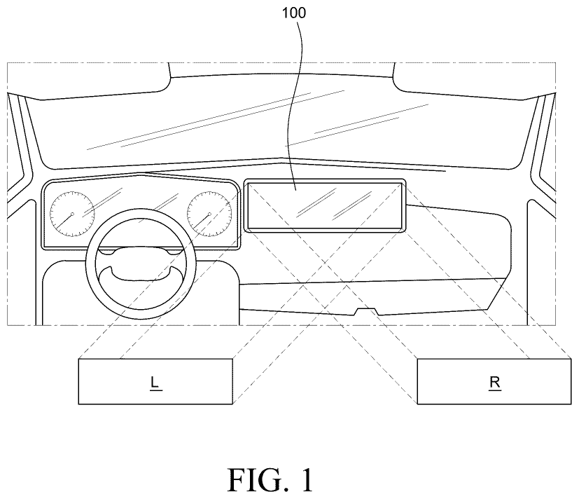

FIG. 1 is an example diagram of a display device according to an example embodiment of the present disclosure.

The display device 100 can be disposed on at least a portion of a dashboard of a vehicle. The dashboard of the vehicle can include, for example, a configuration disposed in front of front seats of the vehicle, such as a driver seat and a passenger seat. For example, the dashboard of the vehicle can be disposed with an input configuration for operating various functions inside the vehicle, such as an air conditioner, an audio system, and a navigation system.

In an example embodiment of the present disclosure, the display device 100 is disposed on the dashboard of the vehicle and can operate as an input unit for operating at least some of the various functions of the vehicle. The display device 100 can provide various information related to the vehicle, for example, driving information of the vehicle such as speed, remaining fuel amount, and driving distance, and information regarding components of the vehicle such as damage to a vehicle tire or tire inflation level. However, embodiments are not limited thereto, and the multi-view display device can be applied to other types of situations, particularly those involving shared spaces, such as working environments, gaming environments, advertisement displays, etc.

In an example embodiment of the present disclosure, the display device 100 can be disposed across the driver seat and the passenger seat disposed in the front seats of the vehicle. A user of the display device 100 can include the driver of the vehicle and a passenger in the passenger seat. Both the driver and the passenger can use the display device 100.

In an example embodiment of the present disclosure, the display device 100 illustrated in FIG. 1 can be partially illustrated. The display device 100 illustrated in FIG. 1 can represent a display panel among various configurations included in the display device 100. Specifically, for example, the display device 100 illustrated in FIG. 1 can represent at least a portion of an active area and a non-active area of the display panel. Configurations other than the portion illustrated in FIG. 1 among the configurations of the display device 100 can be mounted inside (or at least partially) of the vehicle.

Referring to FIG. 1, a driver of the vehicle and a passenger in the passenger seat can view two different contents respectively on left and right sides by using one display device 100. For example, by using one display device 100, the driver can view content L on the left side, and the passenger in the passenger seat can view content R on the right side, but this is not limited thereto.

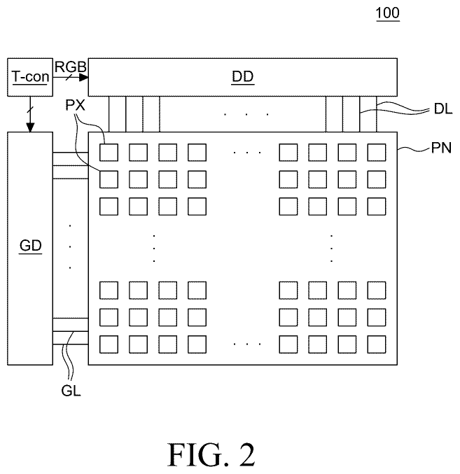

FIG. 2 is a functional block diagram of a display device according to an example embodiment of the present disclosure.

The display device 100 according to an example embodiment of the present disclosure can employ an electroluminescent display device. The electroluminescent display device can include an organic light emitting diode (OLED) display device, a quantum-dot light emitting diode (QLED) display device, or an inorganic light emitting diode display device.

Referring to FIG. 2, the display device 100 according to an example embodiment of the present disclosure can include a display panel PN, a data driving circuit DD, a gate driving circuit GD, and a timing controller T-con.

In an example embodiment, the display panel PN can generate an image to be provided to a user. For example, the display panel PN can generate and display an image to be provided to the user through a plurality of pixels PX, each of which is disposed with a pixel circuit.

The data driving circuit DD, the gate driving circuit GD, and the timing controller T-con can provide signals for driving each pixel PX through signal lines. The signal lines can include, for example, data lines DL and gate lines GL.

In some situations, the display device can further include a power supply unit. In this situation, signals for driving the pixels PX can be provided through power supply lines connecting the power supply unit and the display panel PN. Depending on an example embodiment, the power supply unit can supply power to the data driving circuit DD and the gate driving circuit GD. The data driving circuit DD and the gate driving circuit GD can be driven based on the power provided from the power supply unit.

For example, the data driving circuit DD can apply a data signal to each pixel PX through the data lines DL, the gate driving circuit GD can apply a gate signal to each pixel PX through the gate lines GL, and the power supply unit can supply a power voltage to each pixel PX through power voltage supply lines.

The timing controller T-con can control the data driving circuit DD and the gate driving circuit GD. For example, the timing controller T-con can rearrange digital video data input from outside according to the resolution of the display panel PN and supply it to the data driving circuit DD.

The data driving circuit DD can convert digital video data input from the timing controller T-con into an analog data voltage based on a data control signal and supply the analog data voltage to a plurality of data lines.

The gate driving circuit GD can generate a scan signal and an emission signal (or an emission control signal) based on a gate control signal. The gate driving circuit GD can include a scan driver and a light emitting signal driver. The scan driver can generate a scan signal in a row-sequential manner to drive at least one scan line connected to each pixel row, and can supply the scan signal to the scan lines. The light emitting signal driver can generate a light emitting signal in a row-sequential manner to drive at least one light emitting signal line connected to each pixel row, and can supply the light emitting signal to the light emitting signal lines.

In an example embodiment, the gate driving circuit GD can be disposed in the display panel PN in a gate-driver in panel (GIP) method. For example, the gate driving circuit GD can be divided into a plurality of portions and disposed on at least two side surfaces of the display panel PN.

The display panel PN can include an active area and a non-active area.

The active area can include a plurality of pixels PX. In each pixel PX, a plurality of data lines and a plurality of gate lines can intersect, and sub pixels can be disposed at each of the intersections. Each sub pixel included in one pixel PX can emit light of a different color. For example, the pixel PX can implement blue, red, and green by using three sub pixels. However, the present disclosure is not limited thereto, and in some situations, the pixel PX can further include an additional sub pixel for implementing a specific color, for example, white.

An area that implements blue in the pixel PX can be referred to as a blue sub pixel, an area that implements red can be referred to as a red sub pixel, and an area that implements green can be referred to as a green sub pixel.

The non-active area can be disposed along a periphery of the active area. Various components for driving a pixel circuit disposed in the pixel PX can be disposed in the non-active area. For example, at least a portion of the gate driving circuit GD can be disposed in the non-active area. The non-active area can be referred to as a bezel area.

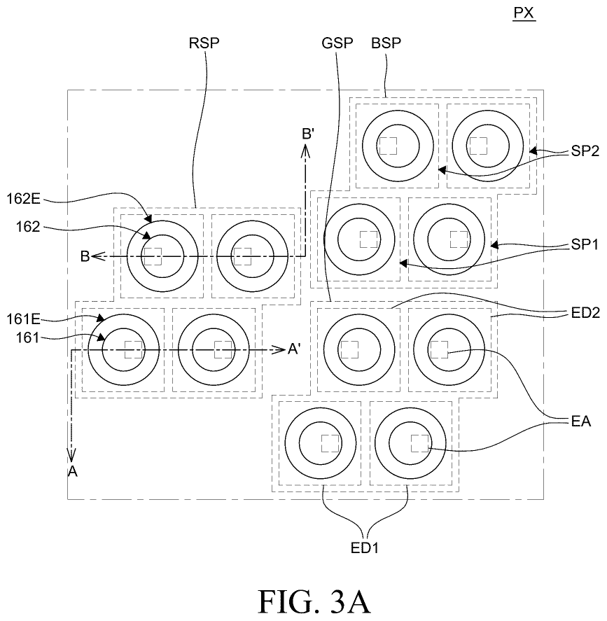

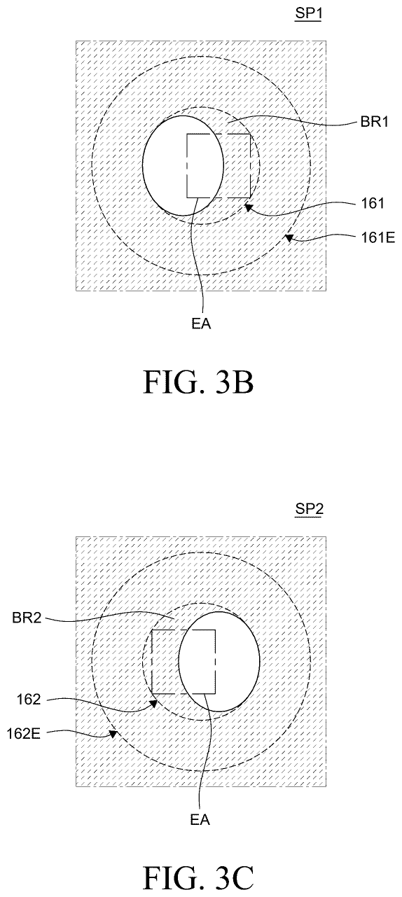

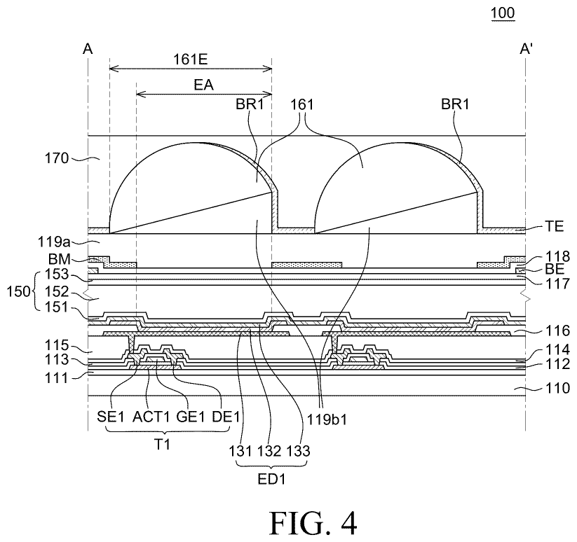

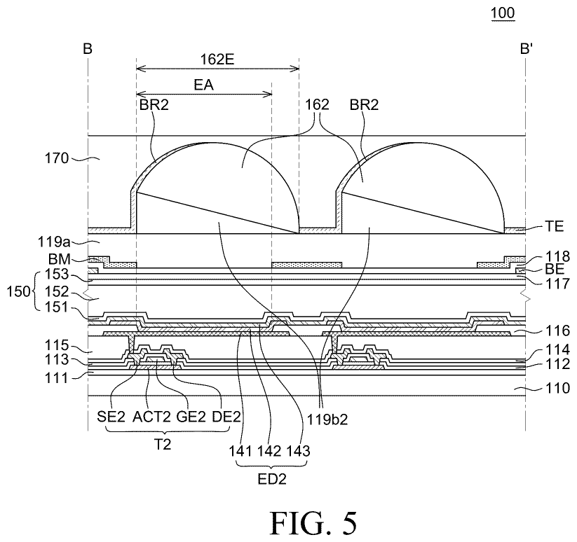

FIG. 3A is an enlarged plan view of one pixel of a display device according to an example embodiment of the present disclosure. FIG. 3B is an enlarged plan view of one first sub pixel of a display device according to an example embodiment of the present disclosure. FIG. 3C is an enlarged plan view of one second sub pixel of a display device according to an example embodiment of the present disclosure. FIG. 4 is a cross-sectional view taken along line A-A′ of FIG. 3A. FIG. 5 is a cross-sectional view taken along line B-B′ of FIG. 3A. FIG. 4 illustrates a cross section of a plurality of first sub pixels SP1 emitting the same color in one pixel PX, and FIG. 5 illustrates a cross section of a plurality of second sub pixels SP2 emitting the same color in one pixel PX. In FIGS. 4 and 5, for convenience of explanation, only the first sub pixel SP1 and the second sub pixel SP2 of a red sub pixel RSP among a plurality of sub pixels RSP, GSP, and BSP are illustrated, but other sub pixels GSP and BSP can be configured to have the same cross section.

First, referring to FIGS. 3A to 3C, each of the plurality of pixels PX can include a plurality of sub pixels RSP, GSP, and BSP representing different colors. For example, each pixel PX can include a blue sub pixel BSP implementing blue, a red sub pixel RSP implementing red, and a green sub pixel GSP implementing green. A pixel circuit can be disposed in each of the plurality of sub pixels RSP, GSP, and BSP. A pixel circuit corresponding to each of the plurality of sub pixels RSP, GSP, and BSP can be disposed. The red, green and blue sub pixels RSP, GSP, and BSP can be arranged in a triangle shaped configuration, but embodiments are not limited thereto.

Each of the plurality of sub pixels RSP, GSP, and BSP can include a first sub pixel SP1 and a second sub pixel SP2 emitting the same color. The first sub pixel SP1 and the second sub pixel SP2 can emit light in different directions. The first sub pixel SP1 can emit light in a first direction (e.g., left direction), and the second sub pixel SP2 can emit light in a second direction (e.g., right direction) opposite to the first direction (e.g., left direction). For example, the first sub pixel SP1 can emit light in the left direction, and the second sub pixel SP2 can emit light in the right direction, but this is not limited thereto. For example, according to another embodiment, the first sub pixel SP1 can emit light in an upward direction, and the second sub pixel SP2 can emit light in a downward direction, etc.

Referring to FIGS. 3A to 5, in each of the plurality of sub pixels RSP, GSP, and BSP, the first sub pixel SP1 includes a first area 161E in which a first transistor T1, a first light emitting diode ED1, and a first light path changing part 161 are disposed, and the second sub pixel SP2 includes a second area 162E in which a second transistor T2, a second light emitting diode ED2, and a second light path changing part 162 are disposed.

In the first sub pixel SP1 of each of the plurality of sub pixels RSP, GSP, and BSP, an area in which the first light path changing part 161 is disposed can be referred to as a first area 161E. For example, the first area 161E can be an area in which light generated by the first light emitting diode ED1 is magnified and emitted through the first light path changing part 161. Accordingly, the size of the first area 161E can be larger than the size of the first light path changing part 161, but is not limited thereto.

In the second sub pixel SP2 of each of the plurality of sub pixels RSP, GSP, and BSP, an area in which the second light path changing part 162 is disposed can be referred to as a second area 162E. For example, the second area 162E can be an area in which light generated by the second light emitting diode ED2 is magnified and emitted through the second light path changing part 162. Accordingly, the size of the second area 162E can be larger than the size of the second light path changing part 162, but is not limited thereto.

The first area 161E and the second area 162E of each of the plurality of sub pixels RSP, GSP, and BSP can have a shape corresponding to the first light path changing part 161 and the second light path changing part 162 disposed in the respective sub pixels RSP, GSP, and BSP. For example, when the planar shape of the first light path changing part 161 and the second light path changing part 162 of each of the plurality of sub pixels RSP, GSP, and BSP is circular or rectangular, the first area 161E and the second area 162E can have a circular or rectangular shape.

Meanwhile, a plurality of first sub pixels SP1 and second sub pixels SP2 can be disposed in each of the plurality of sub pixels RSP, GSP, and BSP. For example, in the red sub pixel RSP of one pixel PX, two first areas 161E and two second areas 162E can be disposed. However, in the red sub pixel RSP of one pixel PX, only one first area 161E and one second area 162E can be disposed, but is not limited thereto.

The first sub pixel SP1 in each of the plurality of sub pixels RSP, GSP, and BSP can operate independently from the second sub pixel SP2. For example, in each of the plurality of sub pixels RSP, GSP, and BSP, the first light emitting diode ED1 located in the first sub pixel SP1 of the plurality of sub pixels RSP, GSP, and BSP and the second light emitting diode ED2 located in the second sub pixel SP2 of the plurality of sub pixels RSP, GSP, and BSP can operate independently.

In the first sub pixel SP1, a first light path changing part 161 for changing a light path of light emitted from the first light emitting diode ED1 is disposed above the first light emitting diode ED1. The first light path changing part 161 is disposed to overlap with an emission area EA of the first light emitting diode ED1 above the first light emitting diode ED1.

In the second sub pixel SP2, a second light path changing part 162 for changing a light path of light emitted from the second light emitting diode ED2 is disposed above the second light emitting diode ED2. The second light path changing part 162 is disposed to overlap with an emission area EA of the second light emitting diode ED2 above the second light emitting diode ED2.

Meanwhile, the emission area EA of the light emitting diodes ED1 and ED2 can be an area in which light emitted from one light emitting diode ED1 or ED2 is emitted through an opening area of a black matrix BM disposed above the light emitting diodes ED1 and ED2, but is not limited thereto.

For example, the first light path changing part 161 can be a first lens that changes a light path of light emitted from the first light emitting diode ED1 to a left direction (e.g., first direction), and the second light path changing part 162 can be a second lens that changes a light path of light emitted from the second light emitting diode ED2 to a right direction (e.g., second direction). However, the present disclosure is not limited thereto, any configuration can be employed as long as it can change a light path (e.g., up, down, or diagonal directions, etc.). The first light path changing part 161 and the second light path changing part 162 can be optical members or optical lenses.

Meanwhile, referring to FIGS. 3A to 5, in the first sub pixel SP1 of each of the plurality of sub pixels RSP, GSP, and BSP, a center of the first light path changing part 161 can be spaced apart by a predetermined interval in a left direction (e.g., first direction) from a center of the first light emitting diode ED1. In the second sub pixel SP2 of each of the plurality of sub pixels RSP, GSP, and BSP, a center of the second light path changing part 162 can be spaced apart by a predetermined interval in a right direction (e.g., second direction) from a center of the second light emitting diode ED2. The center of the first light path changing part 161 can be spaced apart by a predetermined interval in the left direction (first direction) based on the emission area EA of the first light emitting diode ED1. The center of the second light path changing part 162 can be spaced apart by a predetermined interval in the right direction (second direction) based on the emission area EA of the second light emitting diode ED2. For example, to direct light to a specific side, the lens in each sub-pixel can be deliberately offset from its light source. The lens can be shifted to the left of the light source to direct light left, and shifted to the right to direct light right.

In one pixel PX, the first light emitting diode ED1 and the second light emitting diode ED2 can be disposed for each of the first light path changing parts 161 and the second light path changing parts 162 of the plurality of sub pixels RSP, GSP, and BSP.

For example, in one pixel PX, a first light emitting diode ED1 disposed in the first light path changing part 161 of a red sub pixel RSP, a second light emitting diode ED2 disposed in the second light path changing part 162 of the red sub pixel RSP, a first light emitting diode ED1 disposed in the first light path changing part 161 of a green sub pixel GSP, a second light emitting diode ED2 disposed in the second light path changing part 162 of the green sub pixel GSP, a first light emitting diode ED1 disposed in the first light path changing part 161 of a blue sub pixel BSP, and a second light emitting diode ED2 disposed in the second light path changing part 162 of the blue sub pixel BSP can be disposed.

Meanwhile, referring to FIGS. 4 and 5, one light path changing part 161 or 162 can be disposed above one light emitting diode ED1 or ED2. However, as illustrated in FIGS. 3A to 5, when light path changing parts 161 and 162 that change a light path in the same direction in one sub pixel RSP, GSP, or BSP emitting the same color are disposed side by side, the light path changing parts 161 and 162 can be disposed above the same light emitting diode ED1 or ED2. For example, in one sub pixel RSP, GSP, or BSP emitting the same color, when a plurality of first light path changing parts 161 is disposed side by side, the plurality of first light path changing parts 161 can be disposed above one first light emitting diode ED1. In one sub pixel RSP, GSP, or BSP emitting the same color, when a plurality of second light path changing parts 162 is disposed side by side, the plurality of second light path changing parts 162 can be disposed above one second light emitting diode ED2, but is not limited thereto.

Referring to FIGS. 4 and 5, a display device 100 according to an example embodiment of the present disclosure can include a substrate 110, a buffer layer 111, a gate insulating layer 112, an interlayer insulating layer 113, a lower protective layer 114, an overcoat layer 115, a first transistor T1, a second transistor T2, a first light emitting diode ED1, a second light emitting diode ED2, an encapsulation member 150, a touch buffer layer 117, a bridge electrode BE, a touch interlayer insulating layer 118, a black matrix BM, a touch insulating layer 119a, a first additional insulating layer 119b1, a second additional insulating layer 119b2, a first light path changing part 161, a second light path changing part 162, a touch electrode TE, a first barrier part BR1, a second barrier part BR2, and an upper protective layer 170.

The substrate 110 can be disposed to support other components disposed on the substrate 110. The substrate 110 can include an insulating material. The substrate 110 can include a transparent material. For example, the substrate 110 can include glass or plastic, but is not limited thereto.

The buffer layer 111 can be located between the substrate 110 and a driving portion of each of the sub pixels RSP, GSP, and BSP. The buffer layer 111 can suppress contamination of the substrate 110 during a process of forming the driving portion. For example, a top surface of the substrate 110 facing the driving portion of each of the sub pixels RSP, GSP, and BSP can be covered by the buffer layer 111. The driving portion of each of the sub pixels RSP, GSP, and BSP can be located on the buffer layer 111.

The buffer layer 111 can include an insulating material. For example, the buffer layer 111 can include an inorganic insulating material such as silicon oxide (SiOx) and silicon nitride (SiNx). The buffer layer 111 can have a multilayer structure. For example, the buffer layer 111 can have a laminated structure of a film made of silicon nitride (SiNx) and a film made of silicon oxide (SiOx), but is not limited thereto.

The gate insulating layer 112 can be located on the buffer layer 111. The gate insulating layer 112 can extend between a semiconductor layer and a gate electrode of a transistor. For example, the gate electrodes GE1 and GE2 of the first transistor T1 and the second transistor T2 can be insulated from the semiconductor layers ACT1 and ACT2 of the first transistor T1 and the second transistor T2 by the gate insulating layer 112. The gate insulating layer 112 can cover the first semiconductor layer ACT1 and the second semiconductor layer ACT2 of each of the sub pixels RSP, GSP, and BSP. The gate electrodes GE1 and GE2 of the first transistor T1 and the second transistor T2 can be located on the gate insulating layer 112.

The gate insulating layer 112 can include an insulating material. For example, the gate insulating layer 112 can include an inorganic insulating material such as silicon oxide (SiO) and silicon nitride (SiN). The gate insulating layer 112 can include a material having a high dielectric constant. For example, the gate insulating layer 112 can include a high-K material such as hafnium oxide (HfO). The gate insulating layer 112 can have a multilayer structure, but is not limited thereto.

The interlayer insulating layer 113 can be located on the gate insulating layer 112. The interlayer insulating layer 113 can extend between a gate electrode and a source electrode of a transistor and between the gate electrode and a drain electrode of the transistor. For example, the source electrodes SE1 and SE2 and the drain electrodes DE1 and DE2 of the first transistor T1 and the second transistor T2, respectively, can be insulated from the gate electrodes GE1 and GE2 by the interlayer insulating layer 113. The interlayer insulating layer 113 can cover the gate electrodes GE1 and GE2 of the first transistor T1 and the second transistor T2, respectively. The source electrodes SE1 and SE2 and the drain electrodes DE1 and DE2 of each of the sub pixels RSP, GSP, and BSP can be located on the interlayer insulating layer 113. The gate insulating layer 112 and the interlayer insulating layer 113 can expose source regions and drain regions of each semiconductor layer ACT1 or ACT2.

The interlayer insulating layer 113 can include an insulating material. For example, the interlayer insulating layer 113 can include an inorganic insulating material such as silicon oxide (SiO) and silicon nitride (SiN). The interlayer insulating layer 113 can be located on the gate insulating layer 112, but is not limited thereto.

The lower protective layer 114 can be located on the interlayer insulating layer 113. The lower protective layer 114 can suppress damage of a driving portion caused by external moisture and impact. The lower protective layer 114 can extend along a surface of the first transistor T1 and the second transistor T2. The lower protective layer 114 can contact the interlayer insulating layer 113 outside the driving portion located in each of the sub pixels RSP, GSP, and BSP.

The lower protective layer 114 can include an insulating material. For example, the lower protective layer 114 can include an inorganic insulating material such as silicon oxide (SiO) and silicon nitride (SiN), but is not limited thereto.

The overcoat layer 115 can be located on the lower protective layer 114. The overcoat layer 115 can remove a step (e.g., planarize) caused by the driving portion of each of the sub pixels RSP, GSP, and BSP. For example, a top surface of the overcoat layer 115 facing the substrate 110 can be a flat surface.

The overcoat layer 115 can include an insulating material. The overcoat layer 115 can include a material different from the lower protective layer 114. For example, the overcoat layer 115 can include an organic insulating material, but is not limited thereto.

The first transistor T1 can include a first semiconductor layer ACT1, a first gate electrode GE1, a first source electrode SE1, and a first drain electrode DE1.

For example, the first semiconductor layer ACT1 can be located between the buffer layer 111 and the gate insulating layer 112, and the first gate electrode GE1 can be located between the gate insulating layer 112 and the interlayer insulating layer 113. The first source electrode SE1 and the first drain electrode DE1 can be located between the interlayer insulating layer 113 and the lower protective layer 114. The first gate electrode GE1 can overlap with a channel region of the first semiconductor layer ACT1. The first source electrode SE1 can be electrically connected to a source region of the first semiconductor layer ACT1. The first drain electrode DE1 can be electrically connected to a drain region of the first semiconductor layer ACT1.

The second transistor T2 can include a second semiconductor layer ACT2, a second gate electrode GE2, a second source electrode SE2, and a second drain electrode DE2.

For example, the second semiconductor layer ACT2 can be located in the same layer as the first semiconductor layer ACT1, the second gate electrode GE2 can be located in the same layer as the first gate electrode GE1, and the second source electrode SE2 and the second drain electrode DE2 can be located in the same layer as the first source electrode SE1 and the first drain electrode DE1.

The first transistor T1 can be formed simultaneously with the second transistor T2. However, the first transistor T1 and the second transistor T2 can be individually controlled by different signals.

The first light emitting diode ED1 and the second light emitting diode ED2 of each of the sub pixels RSP, GSP, and BSP can be located on the overcoat layer 115 of the respective sub pixels RSP, GSP, and BSP. For example, the first light emitting diode ED1 can be located on the overcoat layer 115 of the first sub pixel SP1, and the second light emitting diode ED2 can be located on the overcoat layer 115 of the second sub pixel SP2.

The first light emitting diode ED1 and the second light emitting diode ED2 can emit light representing a specific color. For example, the first light emitting diode ED1 can include a first lower electrode 131, a first emission layer 132, and a first upper electrode 133 sequentially laminated on the substrate 110.

For example, the first lower electrode 131 of the first light emitting diode ED1 can be electrically connected to the first drain electrode DE1 (or the first source electrode SE1) of the first transistor T1 through a contact hole penetrating the lower protective layer 114 and the overcoat layer 115, and the second lower electrode 141 of the second light emitting diode ED2 can be electrically connected to the second drain electrode DE2 (or the second source electrode SE2) of the second transistor T2 through a contact hole penetrating the lower protective layer 114 and the overcoat layer 115.

The first lower electrode 131 can be an anode electrode of the first light emitting diode ED1, and the first upper electrode 133 can be a cathode electrode of the first light emitting diode ED1.

For example, the first lower electrode 131 can have a multilayer structure including a reflective layer and a transparent conductive layer, and can have a structure in which the reflective layer is located between a plurality of transparent conductive layers. For example, the first lower electrode 131 can include a metal such as aluminum (Al) and silver (Ag), and can be formed of a transparent conductive material such as indium tin oxide (ITO) or indium zinc oxide (IZO), but is not limited thereto.

The first emission layer 132 can generate light of luminance corresponding to a voltage difference between the first lower electrode 131 and the first upper electrode 133. For example, the first emission layer 132 can include an emission material layer (EML) including an emission material. The emission material can include an organic material, an inorganic material, or a hybrid material.

The first emission layer 132 can have a multilayer structure. For example, the first emission layer 132 can further include at least one of a hole injection layer (HIL), a hole transport layer (HTL), an electron transport layer (ETL), and an electron injection layer (EIL).

The first upper electrode 133 can include a conductive material. The first upper electrode 133 can include a material different from the first lower electrode 131. A transmittance of the first upper electrode 133 can be higher than a transmittance of the first lower electrode 131. For example, the first upper electrode 133 can be a transparent electrode made of a transparent conductive material such as ITO and IZO. Alternatively, the first upper electrode 133 can be a transparent electrode formed of a metal material having a very thin thickness. Accordingly, in the display device 100 according to an example embodiment of the present disclosure, light generated by the first emission layer 132 can be emitted through the first upper electrode 133.

The second light emitting diode ED2 can implement the same color as the first light emitting diode ED1 disposed in the same sub pixel RSP, GSP, or BSP. The second light emitting diode ED2 can include a second lower electrode 141, a second emission layer 142, and a second upper electrode 143 sequentially laminated on the substrate 110. In this situation, the second lower electrode 141 can be an anode electrode of the second light emitting diode ED2, and the second upper electrode 143 can be a cathode electrode of the second light emitting diode ED2.

For example, the second lower electrode 141 can have a multilayer structure including a reflective layer and a transparent conductive layer, and can have a structure in which the reflective layer is located between a plurality of transparent conductive layers. For example, the second lower electrode 141 can include a metal such as aluminum (Al) and silver (Ag), and can be formed of a transparent conductive material such as indium tin oxide ITO and indium zinc oxide IZO, but is not limited thereto.

The second emission layer 142 can generate light of luminance corresponding to a voltage difference between the second lower electrode 141 and the second upper electrode 143. For example, the second emission layer 142 can include an emission material layer (EML) including an emission material. The emission material can include an organic material, an inorganic material, or a hybrid material.

The second emission layer 142 can have a multilayer structure. For example, the second emission layer 142 can further include at least one of a hole injection layer (HIL), a hole transport layer (HTL), an electron transport layer (ETL), and an electron injection layer (EIL).

The second upper electrode 143 can include a conductive material. The second upper electrode 143 can include a material different from the second lower electrode 141. A transmittance of the second upper electrode 143 can be higher than a transmittance of the second lower electrode 141. For example, the second upper electrode 143 can be a transparent electrode made of a transparent conductive material such as ITO and IZO. Alternatively, the second upper electrode 143 can be a transparent electrode formed of a metal material having a very thin thickness. Accordingly, in the display device 100 according to an example embodiment of the present disclosure, light generated by the second emission layer 142 can be emitted through the second upper electrode 143.

The second lower electrode 141 of each of the sub pixels RSP, GSP, and BSP can be spaced apart from the first lower electrode 131 of the corresponding sub pixel RSP, GSP, or BSP. For example, a bank insulating layer 116 can be located between the first lower electrode 131 and the second lower electrode 141 of each of the sub pixels RSP, GSP, and BSP. The bank insulating layer 116 can include an insulating material. For example, the bank insulating layer 116 can include an organic insulating material. The bank insulating layer 116 can include a material different from the overcoat layer 115, but is not limited thereto.

The second lower electrode 141 of each of the sub pixels RSP, GSP, and BSP can be insulated from the first lower electrode 131 of the corresponding sub pixel RSP, GSP, or BSP by the bank insulating layer 116. For example, the bank insulating layer 116 can cover an edge of the first lower electrode 131 and an edge of the second lower electrode 141 located in each of the sub pixels RSP, GSP, and BSP.

The bank insulating layer 116 can separate an emission area of the first light emitting diode ED1 and an emission area of the second light emitting diode ED2. For example, the emission area of the first light emitting diode ED1 can be defined as an edge area of the first lower electrode 131 covered by the bank insulating layer 116. The emission area of the second light emitting diode ED2 can be defined as an edge area of the second lower electrode 141 covered by the bank insulating layer 116.

The first emission layer 132 and the first upper electrode 133 of the first light emitting diode ED1 located in each of the sub pixels RSP, GSP, and BSP can be disposed on the first lower electrode 131 and the bank insulating layer 116. Specifically, the first emission layer 132 and the first upper electrode 133 can be laminated on a portion of the first lower electrode 131 exposed by the bank insulating layer 116 and on the bank insulating layer 116. The second emission layer 142 and the second upper electrode 143 of the second light emitting diode ED2 located in each of the sub pixels RSP, GSP, and BSP can be disposed on the second lower electrode 141 and the bank insulating layer 116. Specifically, the second emission layer 142 and the second upper electrode 143 can be laminated on a portion of the second lower electrode 141 exposed by the bank insulating layer 116 and on the bank insulating layer 116.

The second upper electrode 143 of each of the sub pixels RSP, GSP, and BSP can be electrically connected to the first upper electrode 133 of the corresponding sub pixel RSP, GSP, or BSP. For example, a voltage applied to the second upper electrode 143 of the second light emitting diode ED2 located in each of the sub pixels RSP, GSP, and BSP can be the same as a voltage applied to the first upper electrode 133 of the first light emitting diode ED1 located in the corresponding sub pixel RSP, GSP, or BSP. The second upper electrode 143 of each of the sub pixels RSP, GSP, and BSP can include the same material as the first upper electrode 133 of the corresponding sub pixel RSP, GSP, or BSP. For example, the second upper electrode 143 of each of the sub pixels RSP, GSP, and BSP can be formed simultaneously with the first upper electrode 133 of the corresponding sub pixel RSP, GSP, or BSP. The second upper electrode 143 of each of the sub pixels RSP, GSP, and BSP can extend to a top surface of the bank insulating layer 116 to directly contact the first upper electrode 133 of the corresponding sub pixel RSP, GSP, or BSP.

An encapsulation member 150 can be located above the first light emitting diode ED1 and the second light emitting diode ED2 of each of the sub pixels RSP, GSP, and BSP. The encapsulation member 150 can suppress damage of the light emitting diodes ED1 and ED2 caused by external moisture and impact. The encapsulation member 150 can have a multilayer structure. For example, the encapsulation member 150 can include a first encapsulation layer 151, a second encapsulation layer 152, and a third encapsulation layer 153 sequentially laminated, but the example embodiments of the present disclosure are not limited thereto.

The first encapsulation layer 151, the second encapsulation layer 152, and the third encapsulation layer 153 can include an insulating material. The second encapsulation layer 152 can include a material different from the first encapsulation layer 151 and the third encapsulation layer 153. For example, the first encapsulation layer 151 and the third encapsulation layer 153 can be inorganic encapsulation layers including an inorganic insulating material, and the second encapsulation layer 152 can include an organic encapsulation layer including an organic insulating material. Accordingly, the light emitting diodes ED1 and ED2 of the display device 100 can be more effectively suppressed from damage caused by external moisture and impact.

A touch buffer layer 117 can be disposed on the encapsulation member 150. The touch buffer layer 117 can be formed of an inorganic insulating material such as, for example, silicon nitride (SiNx) or silicon oxide (SiOx). The touch buffer layer 117 can be formed by laminating a plurality of insulating layers, but is not limited thereto.

A plurality of bridge electrodes BE can be disposed on the touch buffer layer 117. The plurality of bridge electrodes BE can be disposed in a layer different from a plurality of touch electrodes TE, and can be configured to connect between the plurality of touch electrodes TE.

A touch interlayer insulating layer 118 can be disposed on the plurality of bridge electrodes BE. The touch interlayer insulating layer 118 can be formed of, for example, an inorganic insulating material or an organic insulating material. Accordingly, the touch interlayer insulating layer 118 can electrically insulate the plurality of touch electrodes TE and the plurality of bridge electrodes BE.

A black matrix BM can be disposed on the touch interlayer insulating layer 118. The black matrix BM can be disposed to suppress color mixing of the plurality of sub pixels RSP, GSP, and BSP between the plurality of sub pixels RSP, GSP, and BSP. Accordingly, the black matrix BM can be disposed to overlap with the bank insulating layer 116. An opening area can be disposed in the black matrix BM such that light generated by the first light emitting diode ED1 and the second light emitting diode ED2 is emitted upward through the black matrix BM. The opening area of the black matrix BM can be disposed to correspond to the emission areas of the first light emitting diode ED1 and the second light emitting diode ED2. For example, the opening area of the black matrix BM can at least partially overlap with the emission areas of the first light emitting diode ED1 and the second light emitting diode ED2. A center of the opening area of the black matrix BM corresponding to the first light emitting diode ED1 can be spaced apart or shifted in a first direction (left direction) by a predetermined interval from a center of the first light emitting diode ED1. In addition, a center of the opening area of the black matrix BM corresponding to the second light emitting diode ED2 can be spaced apart or shifted in a second direction (right direction) by a predetermined interval from a center of the second light emitting diode ED2. Also, according to an embodiment, the black matrix BM can be disposed between two adjacent lenses, and a portion of the black matrix BM can overlap with one of the two adjacent lenses while not overlapping with the other lens among the two adjacent lenses, but embodiments are not limited thereto.

A touch insulating layer 119a can be disposed on the black matrix BM. The touch insulating layer 119a can be disposed between the black matrix BM and the plurality of touch electrodes TE and can be configured to insulate the plurality of touch electrodes TE.

The touch insulating layer 119a can include an insulating material. For example, the touch insulating layer 119a can include an organic insulating material or an inorganic insulating material, but is not limited thereto.

A first additional insulating layer 119b1 and a second additional insulating layer 119b2 can be disposed on the touch insulating layer 119a. The first additional insulating layer 119b1 can be disposed in the first sub pixel SP1 on the touch insulating layer 119a, and the second additional insulating layer 119b2 can be disposed in the second sub pixel SP2 on the touch insulating layer 119a. The first additional insulating layer 119b1 and the second additional insulating layer 119b2 can be spaced apart from each other.

The first additional insulating layer 119b1 can include a first inclined surface overlapping the first light emitting diode ED1 on the touch insulating layer 119a, and the second additional insulating layer 119b2 can include a second inclined surface overlapping the second light emitting diode ED2 on the touch insulating layer 119a. For example, a cross-section of each of the first additional insulating layer 119b1 and the second additional insulating layer 119b2 can have a triangular shape, but embodiments are not limited thereto.

The first inclined surface and the second inclined surface can be inclined in different directions. For example, as illustrated in FIG. 4, the first additional insulating layer 119b1 can include the first inclined surface that decreases in height in a first direction (e.g., left direction) from a center of the first light emitting diode ED1. As illustrated in FIG. 5, the second additional insulating layer 119b2 can include the second inclined surface that decreases in height in a second direction (e.g., right direction) from a center of the second light emitting diode ED2.

The first additional insulating layer 119b1 and the second additional insulating layer 119b2 can include an insulating material. For example, the first additional insulating layer 119b1 and the second additional insulating layer 119b2 can include an organic insulating material or an inorganic insulating material, but are not limited thereto.

The first additional insulating layer 119b1 and the second additional insulating layer 119b2 can be formed through a process separate from the touch insulating layer 119a, but the first additional insulating layer 119b1 and the second additional insulating layer 119b2 can also be formed integrally with the touch insulating layer 119a, and the present disclosure is not limited thereto.

A first light path changing part 161 and a second light path changing part 162 can be disposed on the first additional insulating layer 119b1 and the second additional insulating layer 119b2. The first light path changing part 161 can be disposed on the first inclined surface of the first additional insulating layer 119b1, and the second light path changing part 162 can be disposed on the second inclined surface of the second additional insulating layer 119b2. That is, the first light path changing part 161 and the second light path changing part 162 can be disposed on inclined surfaces inclined in different directions, respectively.

The first light path changing part 161 can be disposed to correspond to the first light emitting diode ED1. For example, light generated by the first light emitting diode ED1 of a sub pixel RSP, GSP, or BSP can be emitted in the first direction (e.g., left direction) through the first light path changing part 161 of the corresponding sub pixel RSP, GSP, or BSP. For example, an optical axis of light generated by the first light emitting diode ED1 of the sub pixel RSP, GSP, or BSP can be tilted at a predetermined angle toward the first direction (e.g., left direction) from a vertical axis at the center of the first light emitting diode ED1 by the first light path changing part 161. Accordingly, left-side content L provided through the first light path changing part 161 of one pixel PX can be provided to, for example, a driver of the vehicle, but is not limited thereto.

The second light path changing part 162 can be disposed to correspond to the second light emitting diode ED2. For example, light generated by the second light emitting diode ED2 of a sub pixel RSP, GSP, or BSP can be emitted in the second direction (e.g., right direction) through the second light path changing part 162 of the corresponding sub pixel RSP, GSP, or BSP. For example, an optical axis of light generated by the second light emitting diode ED2 of the sub pixel RSP, GSP, or BSP can be tilted at a predetermined angle toward the second direction (e.g., right direction) from a vertical axis at the center of the second light emitting diode ED2 by the second light path changing part 162. Accordingly, right-side content R provided through the second light path changing part 162 of one pixel PX can be provided to, for example, a passenger seated in the passenger seat of the vehicle, but is not limited thereto.

Meanwhile, an inclination angle of the first inclined surface and the second inclined surface on which the first light path changing part 161 and the second light path changing part 162 are respectively disposed can be 20° to 30° (e.g., 25°). That is, the first light path changing part 161 and the second light path changing part 162 can be disposed on inclined surfaces having an inclination angle of 20° to 30° (e.g., 25°). For example, the first light path changing part 161 and the second light path changing part 162 can be lenses formed by a thermal reflow process. In this situation, when the inclination angle of the first inclined surface and the second inclined surface on which the first light path changing part 161 and the second light path changing part 162 are disposed is excessively high, the first light path changing part 161 and the second light path changing part 162 may not maintain for example, a hemispherical shape and may not function as light path changing parts. Accordingly, by forming the inclination angles of the first inclined surface and the second inclined surface as 20° to 30° (e.g., 25°), the first light path changing part 161 and the second light path changing part 162 can be stably formed. For example, the lenses can be placed on surfaces inclined at an angle of 20° to 30° (e.g., 25°). This specific range can be optimal because if the angle is too steep, the lenses may not form a proper shape during manufacturing and may be lopsided, and if the angle is not steep enough then the two separate views may not be reliably provided and interference may occur. This specific range can ensure that the lenses can be formed stably and function correctly.

A plurality of touch electrodes TE can be located on the touch insulating layer 119a. The plurality of touch electrodes TE can be disposed above the first light emitting diode ED1 and the second light emitting diode ED2 in the active area. The plurality of touch electrodes TE can be spaced apart from each other on the touch insulating layer 119a. The plurality of touch electrodes TE can be configured to sense an external touch input using a user's finger or a touch pen.

Referring to FIGS. 4 and 5, the plurality of touch electrodes TE can be disposed to overlap with the bank insulating layer 116 and the black matrix BM. Accordingly, the plurality of touch electrodes TE can be configured to minimize restricting a light path of light generated by the first light emitting diode ED1 and the second light emitting diode ED2.

For example, the plurality of touch electrodes TE can include a metal material such as titanium (Ti), aluminum (Al), silver (Ag), copper (Cu), or a magnesium-silver alloy (Mg:Ag), but is not limited thereto.

In the plurality of touch electrodes TE, an opening area can be disposed between the plurality of touch electrodes TE such that light emitted from the first light emitting diode ED1 and the second light emitting diode ED2 is emitted upward through the plurality of touch electrodes TE. The opening area between the plurality of touch electrodes TE can be disposed to correspond to the emission areas of the first light emitting diode ED1 and the second light emitting diode ED2. For example, the opening area between the plurality of touch electrodes TE can at least partially overlap with the emission areas of the first light emitting diode ED1 and the second light emitting diode ED2. A center of the opening area between the plurality of touch electrodes TE corresponding to the first light emitting diode ED1 can be spaced apart in a first direction (left direction) by a predetermined interval from a center of the first light emitting diode ED1. In addition, a center of the opening area between the plurality of touch electrodes TE corresponding to the second light emitting diode ED2 can be spaced apart in a second direction (right direction) by a predetermined interval from a center of the second light emitting diode ED2. For example, to let light pass through the touch sensing layer there are openings between the touch electrodes. These openings can align with the light-emitting sub pixels below them and can be also be intentionally offset or shifted to the left for left-directed light and to the right for right-directed light.

Meanwhile, referring to FIGS. 3B, 3C, 4, and 5, a first barrier part BR1 can be disposed on the first light path changing part 161, and a second barrier part BR2 can be disposed on the second light path changing part 162. The first barrier part BR1 and the second barrier part BR2 can be spaced apart from each other.

The first barrier part BR1 and the second barrier part BR2 cover a portion of the top surface of the first light path changing part 161 and the second light path changing part 162. The first barrier part BR1 covers a portion of the top surface of the first light path changing part 161. The second barrier part BR2 covers a portion of the top surface of the second light path changing part 162. The first barrier part BR1 covers a portion of the top surface of the first light path changing part 161 disposed on one side having a higher height among both sides of the first inclined surface of the first additional insulating layer 119b1. The second barrier part BR2 covers a portion of the top surface of the second light path changing part 162 disposed on one side having a higher height among both sides of the second inclined surface of the second additional insulating layer 119b2.

Referring to FIGS. 3B and 4, the first barrier part BR1 is configured to expose a portion in the first direction (left direction) of the top surface of the first light path changing part 161, and to cover a portion in the second direction (right direction) of the top surface of the first light path changing part 161. Accordingly, the first barrier part BR1 can be configured not to restrict light emitted in the first direction (left direction) from the first light path changing part 161, and to shield light emitted in the second direction (right direction) from the first light path changing part 161.

In this situation, referring to FIG. 3B, a planar shape of the first barrier part BR1 overlapping the first light path changing part 161 can be disposed so that a side surface disposed in the first direction (left direction) has a concave shape inward. For example, the planar shape of the first barrier part BR1 overlapping the first light path changing part 161 can be a crescent shape in which a thickness in the horizontal direction is thicker than a thickness in the vertical direction. That is, a planar shape of the first light path changing part 161 which is exposed from the first light path changing part 161 can be an elliptical shape, but is not limited thereto.

When the planar shape of the first barrier part BR1 overlapping the first light path changing part 161 is, for example, a crescent shape in which a side surface disposed in the first direction (left direction) has a concave shape inward, the first barrier part BR1 can be configured to further expose the first light path changing part 161 by a size corresponding to the concave shape in the planar surface. Accordingly, the first barrier part BR1 can maximize an exposed size of the first light path changing part 161, thereby minimizing a size of the first barrier part BR1 that shields light emitted from the first light path changing part 161. Therefore, light emission efficiency of light emitted from the first light path changing part 161 can be improved.

Also, the planar shape of the first barrier part BR1 overlapping the first light path changing part 161 can be disposed so that a side surface disposed in the first direction (left direction) has a linear shape. For example, the planar shape of the first barrier part BR1 overlapping the first light path changing part 161 can be a semicircular shape with a straight side surface in the first direction (left direction). That is, the planar shape of the first light path changing part 161 which is exposed from the first light path changing part 161 can be a semicircular shape, but is not limited thereto.

When the planar shape of the first barrier part BR1 overlapping the first light path changing part 161 is, for example, a semicircular shape with a straight side surface disposed in the first direction (left direction), the first barrier part BR1 can be configured to further shield the first light path changing part 161 by a size corresponding to the semicircular shape in the planar surface. Accordingly, the first barrier part BR1 can be configured to more reliably shield light emitted in a direction other than the first direction (left direction) among light emitted from the first light path changing part 161. Therefore, the dual display of the display device 100 can be more reliably implemented. For example, a light blocking barrier (e.g., first barrier part BR1) can be coated on a portion of each lens to prevent light from going in the wrong direction. For a lens that directs light to the left, the barrier can be coated over the right side of the lens while leaving the left side exposed. Also, according to embodiments, the first barrier part BR1 can have crescent shape in a plan view to maximize the exposed area of the lens which can improve overall brightness and efficiency. According to another embodiment, the first barrier part BR1 can have semi-circle shape in a plan view to better block stray light and reliably separate the two images.

Referring to FIGS. 3C and 5, the second barrier part BR2 is configured to expose a portion in the second direction (right direction) of the top surface of the second light path changing part 162, and to cover a portion in the first direction (left direction) of the top surface of the second light path changing part 162. Accordingly, the second barrier part BR2 can be configured not to restrict light emitted in the second direction (right direction) from the second light path changing part 162, and to shield light emitted in the first direction (left direction) from the second light path changing part 162->162.

In this situation, referring to FIG. 3C, a planar shape of the second barrier part BR2 overlapping the second light path changing part 162 can be disposed so that a side surface disposed in the second direction (right direction) has a concave shape inward. For example, the planar shape of the second barrier part BR2 overlapping the second light path changing part 162 can be a crescent shape in which a thickness in the horizontal direction is thicker than a thickness in the vertical direction. That is, a planar shape of the second light path changing part 162 which is exposed from the second light path changing part 162 can be an elliptical shape, but is not limited thereto.

When the planar shape of the second barrier part BR2 overlapping the second light path changing part 162 is, for example, a crescent shape in which a side surface disposed in the second direction (right direction) has a concave shape inward, the second barrier part BR2 can be configured to further expose the second light path changing part 162 by a size corresponding to the concave shape in the planar surface. Accordingly, the second barrier part BR2 can maximize an exposed size of the second light path changing part 162, thereby minimizing a size of the second barrier part BR2 that shields light emitted from the second light path changing part 162. Therefore, light emission efficiency of light emitted from the second light path changing part 162 can be improved.

Also, the planar shape of the second barrier part BR2 overlapping the second light path changing part 162 can be disposed so that a side surface disposed in the second direction (right direction) has a linear shape. For example, the planar shape of the second barrier part BR2 overlapping the second light path changing part 162 can be a semicircular shape with a straight side surface in the second direction (right direction). That is, the planar shape of the second light path changing part 162 which is exposed from the second light path changing part 162 can be a semicircular shape, but is not limited thereto.

When the planar shape of the second barrier part BR2 overlapping the second light path changing part 162 is, for example, a semicircular shape with a straight side surface disposed in the second direction (right direction), the second barrier part BR2 can be configured to further shield the second light path changing part 162 by a size corresponding to the semicircular shape in the planar surface. Accordingly, the second barrier part BR2 can be configured to more reliably shield light emitted in a direction other than the second direction (right direction) among light emitted from the second light path changing part 162. Therefore, the dual display of the display device 100 can be more reliably implemented. For example, a light blocking barrier (e.g., second barrier part BR2) can be coated on a portion of each lens to prevent light from going in the wrong direction. For a lens that directs light to the right, the barrier can be coated over the left side of the lens while leaving the right side exposed. Also, according to embodiments, the second barrier part BR2 can have crescent shape in a plan view to maximize the exposed area of the lens which can improve overall brightness and efficiency. According to another embodiment, the second barrier part BR2 can have semi-circle shape in a plan view to better block stray light and reliably separate the two images.

Meanwhile, the first barrier part BR1 and the second barrier part BR2 can be formed of a material having, for example, a characteristic of shielding light. The first barrier part BR1 and the second barrier part BR2 can be formed of the same material as the plurality of touch electrodes TE, but are not limited thereto.

For example, when the first barrier part BR1 and the second barrier part BR2 are formed of the same material as the plurality of touch electrodes TE, the first barrier part BR1 and the second barrier part BR2 can be disposed without securing a space for adding separate wiring lines. Accordingly, when the first barrier part BR1 and the second barrier part BR2 are formed of the same material as the plurality of touch electrodes TE, there can be an advantageous effect in securing space for line design. According to an embodiment, the first barrier part BR1 and the second barrier part BR2 can be part of a corresponding touch electrode, but embodiments are not limited thereto. For example, according to an embodiment, the first barrier part BR1 and the second barrier part BR2 can be separate from the touch electrodes even though they can all be formed of the same material, and the first barrier part BR1 and the second barrier part BR2 can be electrically floated.

By disposing a plurality of sub pixels in one pixel to emit light in different directions, a dual display technology can be applied to the display device such that two different contents, for example, contents for a driver of a vehicle and a passenger in a passenger seat, can be viewed by using one display panel.

However, when the dual display is not stably implemented due to deterioration in the functions of a plurality of lenses that change light paths in different directions, contents can be visible even in a direction opposite to the direction intended to be provided by the plurality of lenses. In this situation, when the person who should not share the content is the driver of the vehicle, a serious safety problem can occur.

In the display device 100 according to an example embodiment of the present disclosure, the first light path changing part 161 and the second light path changing part 162 are disposed on a first inclined surface and a second inclined surface inclined in different directions, and the first barrier part BR1 and the second barrier part BR2 covering a portion of the top surfaces of the first light path changing part 161 and the second light path changing part 162 are disposed. Accordingly, the dual display of the display device 100 can be stably implemented.

Specifically, in the display device 100 according to an example embodiment of the present disclosure, the first light path changing part 161 is disposed to correspond to the first light emitting diode ED1, and the second light path changing part 162 is disposed to correspond to the second light emitting diode ED2. The first light path changing part 161 is disposed on the first inclined surface of the first additional insulating layer 119b1, and the second light path changing part 162 is disposed on the second inclined surface of the second additional insulating layer 119b2 inclined in a direction different from the first inclined surface. The first barrier part BR1 and the second barrier part BR2 having a light shielding property are disposed on the first light path changing part 161 and the second light path changing part 162. The first barrier part BR1 and the second barrier part BR2 are disposed to cover a portion of the top surfaces of the first light path changing part 161 and the second light path changing part 162. That is, the first barrier part BR1 can be configured not to restrict light emitted in the first direction (e.g., left direction) from the first light path changing part 161, and to shield light emitted in the second direction (e.g., right direction) from the first light path changing part 161. In addition, the second barrier part BR2 can be configured not to restrict light emitted in the second direction (e.g., right direction) from the second light path changing part 162, and to shield light emitted in the first direction (e.g., left direction) from the second light path changing part 162. Accordingly, the first barrier part BR1 and the second barrier part BR2 can be configured to shield light emitted in a direction other than the intended directions from the first light path changing part 161 and the second light path changing part 162. Therefore, in the display device 100 according to an example embodiment of the present disclosure, by disposing the first light path changing part 161 and the second light path changing part 162 on the first inclined surface and the second inclined surface inclined in different directions and disposing the first barrier part BR1 and the second barrier part BR2 covering a portion of the top surfaces of the first light path changing part 161 and the second light path changing part 162, the dual display of the display device 100 can be stably implemented and the reliability of the dual display function can be improved. Accordingly, serious safety problems caused by sharing content that should not be shared with the driver of the vehicle can be minimized.

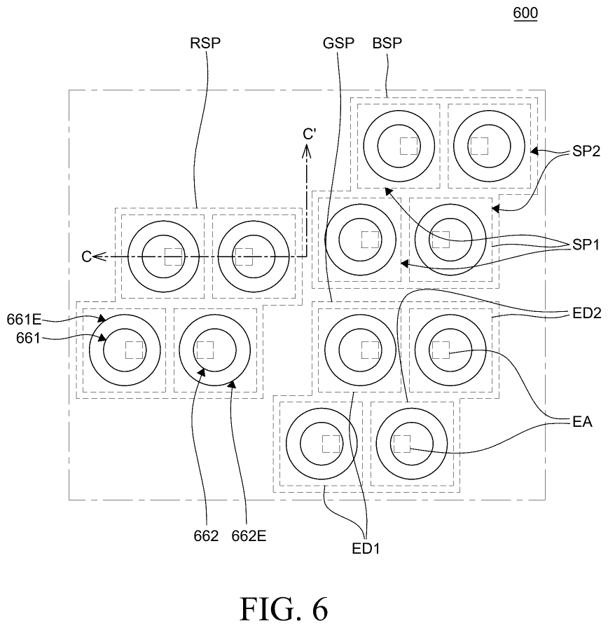

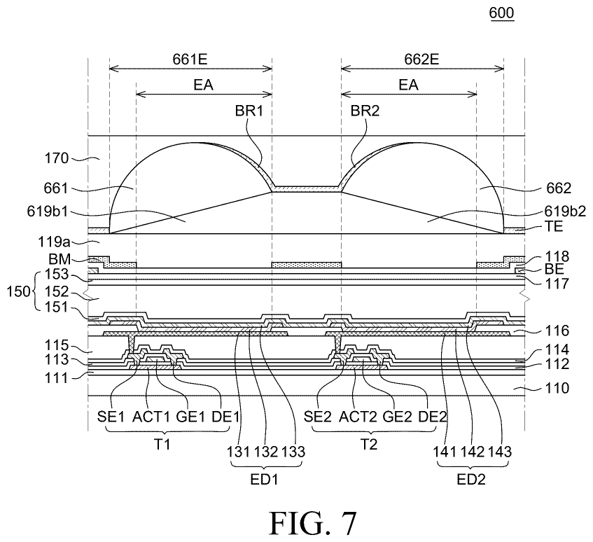

FIG. 6 is an enlarged plan view of one pixel of a display device according to another example embodiment of the present disclosure. FIG. 7 is a cross-sectional view taken along line C-C′ of FIG. 6. The display device 600 of FIGS. 6 and 7 differs from the display device 100 of FIGS. 1 to 5 only in the shapes of the first additional insulating layer 619b1 and the second additional insulating layer 619b2, and the other configurations are the same, so redundant description will be omitted.

Referring to FIG. 6, in one pixel PX, the first light path changing parts 661 and the second light path changing parts 662 of a plurality of sub pixels RSP, GSP, and BSP can be disposed side by side in left and right directions. For example, the first light path changing part 661 of the first sub pixel SP1 and the second light path changing part 662 of the second sub pixel SP2 that emit the same color can be disposed in the same row. That is, the first area 661E of the first sub pixel SP1 and the second area 662E of the second sub pixel SP2 that emit the same color can be disposed in the same row.

Referring to FIG. 7, the first additional insulating layer 619b1 and the second additional insulating layer 619b2 can be formed integrally. In the integrally formed first additional insulating layer 619b1 and second additional insulating layer 619b2, a first inclined surface of the first additional insulating layer 619b1 can be disposed in a first direction (e.g., left direction), and a second inclined surface of the second additional insulating layer 619b2 can be disposed in a second direction (e.g., right direction). For example, a single, integrated insulating layer part can be formed with two surfaces sloping in opposite directions, in which one surface is inclined to the left and the other surface is inclined to the right. Also, a cross-section of the integrally formed first additional insulating layer 619b1 and second additional insulating layer 619b2 can have a trapezoid shape.

Referring to FIG. 7, the first light path changing part 661 and the second light path changing part 662 are respectively disposed on the integrally formed first additional insulating layer 619b1 and second additional insulating layer 619b2. In the integrally formed first additional insulating layer 619b1 and second additional insulating layer 619b2, the first light path changing part 661 is disposed on the first inclined surface of the first additional insulating layer 619b1, and the second light path changing part 662 is disposed on the second inclined surface of the second additional insulating layer 619b2. Accordingly, the first light path changing part 661 and the second light path changing part 662 disposed on the inclined surfaces in different directions can be configured to change light paths in different directions.

Referring to FIG. 7, the first barrier part BR1 is disposed on the first light path changing part 661, and the second barrier part BR2 is disposed on the second light path changing part 662. The first barrier part BR1 and the second barrier part BR2 can be formed integrally. In this situation, the integrally formed first barrier part BR1 and second barrier part BR2 can be electrically floating.

In the display device 600 according to another example embodiment of the present disclosure, by disposing the first light path changing part 661 and the second light path changing part 662 on the integrally formed first additional insulating layer 619b1 and second additional insulating layer 619b2, respectively, the dual display of the display device 600 can be stably implemented.

Specifically, in the display device 600 according to another example embodiment of the present disclosure, the first light path changing part 661 and the second light path changing part 662 are respectively disposed on the integrally formed first additional insulating layer 619b1 and second additional insulating layer 619b2. The first light path changing part 661 is disposed on the first inclined surface of the first additional insulating layer 619b1, and the second light path changing part 662 is disposed on the second inclined surface of the second additional insulating layer 619b2 inclined in a direction different from the first inclined surface. In this situation, a first barrier part BR1 and a second barrier part BR2 having a light shielding property are disposed on the first light path changing part 661 and the second light path changing part 662. The first barrier part BR1 and the second barrier part BR2 are disposed to cover a portion of the top surfaces of the first light path changing part 661 and the second light path changing part 662. That is, the first barrier part BR1 can be configured not to restrict light emitted in the first direction (e.g., left direction) from the first light path changing part 661, and to shield light emitted in the second direction (e.g., right direction) from the first light path changing part 661. In addition, the second barrier part BR2 can be configured not to restrict light emitted in the second direction (e.g., right direction) from the second light path changing part 662, and to shield light emitted in the first direction (e.g., left direction) from the second light path changing part 662. Accordingly, the first barrier part BR1 and the second barrier part BR2 can be configured to shield light emitted in a direction other than the intended directions from the first light path changing part 661 and the second light path changing part 662. Therefore, in the display device 600 according to another example embodiment of the present disclosure, by disposing the first light path changing part 661 and the second light path changing part 662 on the integrally formed first additional insulating layer 619b1 and second additional insulating layer 619b2, the dual display of the display device 600 can be stably implemented and the reliability of the dual display function can be improved. For example, this configuration can create a reliable dual-view display by placing lenses on a sloped insulating layer and then adding a light-blocking barrier on top of each lens. Also, each barrier can be positioned to shield the lens and block any light traveling in the wrong direction. Further, the first barrier part BR1 and the second barrier part BR2 can be integrally formed as one piece or as a same layer, and disposed on and between adjacent lenses, which can improve sticking and prevent peeling. This structure can improve the reliability of the dual-view display which is a safety feature for preventing a driver from being distracted by passenger side content in a vehicle. Accordingly, serious safety problems caused by sharing content that should not be shared with the driver of the vehicle can be further minimized.

The example embodiments of the present disclosure can also be described as follows:

A display device according to an example embodiment of the present disclosure includes: a substrate in which a first sub pixel and a second sub pixel emitting the same color are defined; a first light emitting diode disposed on the substrate and disposed in the first sub pixel; a second light emitting diode disposed on the substrate, disposed in the second sub pixel, and emitting the same color as the first light emitting diode; an insulating layer disposed above the first light emitting diode and the second light emitting diode; a first additional insulating layer disposed on the insulating layer and including a first inclined surface overlapping the first light emitting diode; a second additional insulating layer disposed on the insulating layer, overlapping the second light emitting diode, and including a second inclined surface inclined in a direction different from the first inclined surface; a first light path changing part disposed on the first inclined surface; a second light path changing part disposed on the second inclined surface; and a barrier part disposed on the first additional insulating layer and the second additional insulating layer and covering a part of top surfaces of the first light path changing part and the second light path changing part.

The barrier part can cover a portion of the top surface of the first light path changing part disposed on one side with a higher height of both sides of the first inclined surface, and can cover a portion of the top surface of the second light path changing part disposed on one side with a higher height of both sides of the second inclined surface.

The barrier part can include a first barrier part covering a portion of the top surface of the first light path changing part; and a second barrier part covering a portion of the top surface of the second light path changing part and spaced apart from the first barrier part.

The first additional insulating layer and the second additional insulating layer can be spaced apart from each other.

The barrier part can include a first barrier part covering a portion of the top surface of the first light path changing part; and a second barrier part covering a portion of the top surface of the second light path changing part and formed integrally with the first barrier part.

The first additional insulating layer and the second additional insulating layer can be formed integrally.

The first barrier part and the second barrier part can be electrically floating.

A center of the first light path changing part can be spaced apart at a predetermined interval in a first direction from a center of the first light emitting diode, and a center of the second light path changing part can be spaced apart at a predetermined interval in a second direction opposite to the first direction from a center of the second light emitting diode.

A plurality of the first light path changing parts can be disposed on the first light emitting diode, and a plurality of the second light path changing parts can be disposed on the second light emitting diode.

An inclination angle of the first inclined surface and the second inclined surface can be 20° to 30° (e.g., 25°).

A display device according to another example embodiment of the present disclosure includes; a substrate in which a first sub pixel in which light is emitted in a first direction and a second sub pixel emitting the same color as the first sub pixel and in which light is emitted in a second direction different from the first direction are defined; a first light emitting diode disposed on the substrate and disposed in the first sub pixel; a second light emitting diode disposed on the substrate, disposed in the second sub pixel, and emitting the same color as the first light emitting diode; an insulating layer disposed above the first light emitting diode and the second light emitting diode; a first additional insulating layer disposed on the insulating layer and including a first inclined surface overlapping the first light emitting diode; a second additional insulating layer disposed on the insulating layer, overlapping the second light emitting diode, and including a second inclined surface inclined in a direction different from the first inclined surface; a first light path changing part disposed on the first inclined surface and changing a light path of light emitted from the first light emitting diode to the first direction; a second light path changing part disposed on the second inclined surface and changing a light path of light emitted from the second light emitting diode to the second direction; and a barrier part disposed on the first additional insulating layer and the second additional insulating layer and covering a part of top surfaces of the first light path changing part and the second light path changing part.

The first direction can be a left direction, and the second direction can be a right direction.

The barrier part can include a first barrier part covering a portion of the top surface of the first light path changing part; and a second barrier part covering a portion of the top surface of the second light path changing part and spaced apart from the first barrier part.

The first additional insulating layer and the second additional insulating layer can be spaced apart from each other.

The barrier part can include a first barrier part covering a portion of the top surface of the first light path changing part; and a second barrier part covering a portion of the top surface of the second light path changing part and formed integrally with the first barrier part.

The first additional insulating layer and the second additional insulating layer can be formed integrally.

The first barrier part and the second barrier part can be electrically floating.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first sub pixel and a second sub pixel disposed on a substrate and configured to emit a same color of light;
a first light emitting diode disposed in the first sub pixel;
a second light emitting diode disposed in the second sub pixel, and configured to emit a same color of light as the first light emitting diode;
an insulating layer disposed on the first light emitting diode and the second light emitting diode;
a first additional insulating layer disposed on the insulating layer and including a first inclined surface overlapping with the first light emitting diode;
a second additional insulating layer disposed on the insulating layer, overlapping with the second light emitting diode, and including a second inclined surface inclined in a direction different from the first inclined surface;
a first light path changing part disposed on the first inclined surface of the first additional insulating layer;
a second light path changing part disposed on the second inclined surface of the second additional insulating layer; and
a barrier part disposed on the first additional insulating layer and the second additional insulating layer and covering a portion of a top surface of the first light path changing part and a portion of a top surface of the second light path changing part.

2. The display device of claim 1, wherein the first light path changing part has a first elevated side and a first lower side opposite to the first elevated side,
wherein the second light path changing part has a second elevated side and a second lower side opposite to the second elevated side, and
wherein the barrier part overlaps with the first elevated side of the first light path changing part and the second elevated side of the second light path changing part.

3. The display device of claim 2, wherein the barrier part includes:
a first barrier part covering a portion of the top surface of the first light path changing part; and
a second barrier part covering a portion of the top surface of the second light path changing part and spaced apart from the first barrier part.

4. The display device of claim 3, wherein the first additional insulating layer and the second additional insulating layer are spaced apart from each other.

5. The display device of claim 2, wherein the barrier part includes:
a first barrier part covering a portion of the top surface of the first light path changing part; and
a second barrier part covering a portion of the top surface of the second light path changing part and formed integrally with the first barrier part.

6. The display device of claim 5, wherein the first additional insulating layer and the second additional insulating layer are formed integrally.

7. The display device of claim 6, wherein the first barrier part and the second barrier part are electrically floating.

8. The display device of claim 1, wherein a center of the first light path changing part is spaced apart at a first predetermined interval in a first direction from a center of the first light emitting diode, and
wherein a center of the second light path changing part is disposed spaced apart at a second predetermined interval in a second direction opposite to the first direction from a center of the second light emitting diode.

9. The display device of claim 1, wherein a plurality of the first light path changing parts are disposed on the first light emitting diode, and a plurality of the second light path changing parts are disposed on the second light emitting diode.

10. The display device of claim 1, wherein an inclination angle of the first inclined surface is 20° to 30°, and
wherein an inclination angle of the second inclined surface is 20°to 30.

11. A display device, comprising:
a first sub pixel disposed on a substrate and configured to emit a same color of light in a first direction;
a second sub pixel disposed on the substrate and configured to emit the same color of light in a second direction different from the first direction;
a first light emitting diode disposed in the first sub pixel;
a second light emitting diode disposed in the second sub pixel, and configured to emit a same color as the first light emitting diode;
an insulating layer disposed on the first light emitting diode and the second light emitting diode;
a first additional insulating layer disposed on the insulating layer and including a first inclined surface overlapping with the first light emitting diode;
a second additional insulating layer disposed on the insulating layer, overlapping with the second light emitting diode, and including a second inclined surface inclined in a direction different from the first inclined surface;
a first light path changing part disposed on the first inclined surface of the first additional insulating layer and configured to change a light path of light emitted from the first light emitting diode to the first direction;
a second light path changing part disposed on the second inclined surface of the second additional insulating layer and configured to change a light path of light emitted from the second light emitting diode to the second direction; and
a barrier part disposed on the first additional insulating layer and the second additional insulating layer and covering a portion of a top surface of the first light path changing part and a portion of a top surface of the second light path changing part.

12. The display device of claim 11, wherein the first direction is a left direction, and the second direction is a right direction.

13. The display device of claim 11, wherein the barrier part includes:
a first barrier part covering a portion of the top surface of the first light path changing part; and
a second barrier part covering a portion of the top surface of the second light path changing part and spaced apart from the first barrier part.

14. The display device of claim 13, wherein the first additional insulating layer and the second additional insulating layer are spaced apart from each other.

15. The display device of claim 11, wherein the barrier part includes:
a first barrier part covering a portion of the top surface of the first light path changing part; and
a second barrier part covering a portion of the top surface of the second light path changing part and formed integrally with the first barrier part.

16. The display device of claim 15, wherein the first additional insulating layer and the second additional insulating layer are formed integrally.

17. The display device of claim 15, wherein the first barrier part and the second barrier part are electrically floating.

18. A display device, comprising:
a first sub pixel and a second sub pixel disposed on a substrate and configured to emit a same color of light;
a first light emitting diode disposed in the first sub pixel;
a second light emitting diode disposed in the second sub pixel;
a first inclined insulating portion disposed on the first light emitting diode;
a second inclined insulating portion disposed on the second light emitting diode;
a first lens disposed on the first inclined insulating portion and configured to change a direction of light emitted from the first light emitting diode; and
a second lens disposed on the second inclined insulating portion and configured to change a direction of light emitted from the second light emitting diode.

19. The display device of claim 18, wherein the first inclined insulating portion is formed integrally with the second inclined insulating portion.

20. The display device of claim 18, wherein the first inclined insulating portion is tilted in a first direction, and
wherein the second inclined insulating portion is tilted in a second direction different than the first direction.

21. The display device of claim 20, further comprising:
a first barrier part disposed on a portion of the first lens, wherein the first barrier part is configured to permit light to travel in the first direction and block light from traveling in the second direction.

22. The display device of claim 21, wherein the first barrier part has a crescent shape in a plan view.

23. The display device of claim 20, wherein an angle of the first inclined insulating portion relative to the substrate is 20° to 30°, and
wherein an angle of the second inclined insulating portion relative to the substrate is 20° to 30°.

24. The display device of claim 18, wherein a center of the first lens is offset from a center of the first light emitting diode, and
wherein a center of the second lens is offset from a center of the second light emitting diode.
